(19) United States
(12) Patent Application Publication
(10) Pub. No.: US 2014/0264938 A1
(43) Pub. Date: Sep. 18, 2014

(54) Flexible Interconnect

(71) Applicants: Douglas R. Hackler, SR., Boise, ID (US); Dale G. Wilson, Kuna, ID (US)

(72) Inventors: Douglas R. Hackler, SR., Boise, ID (US); Dale G. Wilson, Kuna, ID (US)

(21) Appl. No.: 14/213,417

(22) Filed: Mar. 14, 2014

Related U.S. Application Data
(60) Provisional application No. 61/785,501, filed on Mar. 14, 2013.

(51) Int. Cl. H01L 23/48

(52) U.S. Cl. CPC H01L 23/481
USPC 257/774

(57) ABSTRACT

The described Flexible Interconnect is useful for making electrical or other contact between various combinations of semiconductor die, printed circuit boards and other components. A thin flexible material, such as a polymer, supports printed lines that connect pads which may contain vias. The flexible interconnect can be attached using conductive and non-conductive epoxies to the components that are to be interconnected. Each interconnect can be individually insulated from adjacent interconnects, so that it can be deformed and flexed without making contact with another. The described interconnects can span long distances and conform to underlying topography. Metal interconnects may be used to conduct heat or to form heat sinks. Similarly, flexible interconnects may be formed from material that is an electrical insulator but thermally conductive in order to transport heat away from the attached circuitry. Optical conductors may be supported for use as flexible photonic waveguides.

### CROSS-REFERENCES TO RELATED APPLICATIONS

This application claims benefit of U.S. Provisional Application No. 61/785,501 filed Mar. 14, 2013, entitled “Flexible Interconnect”, which is incorporated here by reference in its entirety.

This application is related to International Application No. PCT/US14/14740 filed Feb. 4, 2014, entitled “Photonic Data Transfer Assembly”, which application also claims benefit of U.S. Provisional Application No. 61/785,501.

### FIELD OF THE INVENTION

The present invention relates generally to a device for interconnecting electronic circuits. In particular, the described devices and methods pertain to flexible interconnects.

### BACKGROUND OF THE INVENTION

Until now the mounting of semiconductor die followed by the forming of interconnections on flexible circuits has focused on traditional methods of die attach with subsequent formation of wire interconnects or some type of flip chip ball or solder. Individual bonds have been made independently, one at a time, using wire or some form of bump or ball bond. Die attach has commonly been performed using eutectic, solder or epoxy bonding techniques. Though epoxy die attach is well suited to flexible assembly, interconnects between the die and package, between one die and another, or from a die directly to a circuit board has been typically accomplished by wire bonds or bump bonds or solder. Traditional interconnect methods are quite effective for rigid die, but fail to meet most requirements for flexible electronics.

A more recent method of providing flexible interconnects to flexible substrates uses flexible springs. Flexible semiconductor circuits are generally available and flexible “plastic” CMOS has been demonstrated, but a truly flexible means of interconnecting them is not presently recognized.

### BRIEF SUMMARY OF THE INVENTION

The methods and devices described here relate to the creation of flexible circuit interconnects by means of a flexible overlay that can bridge between the devices that are to be interconnected. The produced interconnect conforms to the underlying topography. It may serve as either a conductor or as an insulator. It remains flexible and is capable of routing interconnect signal paths and providing low resistance electrical contacts.

As described, a basic interconnect includes a thin flexible material with at least one printed line having a connection pad at each end of the line to create a flexible interconnect. Attachment of the flexible interconnect to an assembly may use materials such as conductive and non-conductive epoxies. The conductive epoxies or similar material can be applied to directly connect the interconnect pad to the pad of the die being contacted with the two surfaces coming into contact when the flexible interconnect is applied.

By patterning of a via (through-hole) completely through the pads of the flexible interconnect, connection can be made between a pad on a die and the flexible interconnect pad surface on the side that is not adjacent to the die. The flexible interconnect can be adhered to the substrate with non-conductive epoxy or with an adhesive. Gaps between the flexible substrate, the die and substrate may also be filled with non-conductive adhesive or epoxy. The connection is made by printing a fill of conductive material, such as conductive epoxy, into the via. The conductive material serves as a short circuit to the die pad, fills the via and overlaps the top of the flexible interconnect pad to form an electrical path from the die pad to the flexible interconnect pad.

Each interconnect can be individually insulated from adjacent interconnects, so that they can be deformed and flexed without coming into contact with one other. The described interconnects can span long distances and conform to underlying topography. Metal interconnects may be used to conduct heat or to form heat sinks. Similarly, flexible interconnects may be formed from material that is an electrical insulator but thermally conductive in order to transport heat away from the attached circuitry.

### BRIEF DESCRIPTION OF THE DRAWINGS

The particular features and advantages of the invention will become apparent from the following description taken in conjunction with one or more of the accompanying FIGS. 1-8 of the drawings:

FIG. 1 is a cross-section of a basic flexible interconnect showing two layers of metal with pads;

FIG. 2 illustrates the flexible interconnect of FIG. 1 when flexed;

FIG. 3 is a top view of a flexible interconnect including pads with vias;

FIG. 4 is a cross-section view of flexible interconnect of FIG. 3;

FIG. 5 shows the flexible interconnect of FIG. 4 when flexed;

FIG. 6 depicts in cross-section a flexible interconnect with vias interconnecting pads of a flexible printed circuit board (PCB) with the pads of a semiconductor die;

FIG. 7 shows a top view of a flexible interconnect providing multiple interconnections; and

FIG. 8 illustrates multiple semiconductor die connected by a flexible interconnect to each other and to the underlying substrate.

The following Reference Numbers may be used in conjunction with one or more of the accompanying FIGS. 1-8 of the drawings:

100 flexible interconnect

110 pad on flexible interconnect

120 metal

130 via

140 flexible printed circuit board (PCB)

150 die, semiconductor chip

160 bonding pad on semiconductor chip

170 conductive epoxy

180 non-conductive epoxy

190 polymer

200 substrate

### DETAILED DESCRIPTION OF THE INVENTION

The flexible interconnect described here enables interconnections between various combinations of semiconductor die and printed circuit boards, such as those components used to build a smart card. A basic interconnect includes a thin flexible material with at least one printed line having a connection pad at each end of the line to create a flexible interconnect. As shown here beginning in FIG. 1, the flexible interconnect 100 is made from a flexible non-conductive material such as polymer 190. The large flexible surface area material provides a structure on which various features can be printed, patterned, deposited or etched. Conductive pads 110 and metal lines 120 may be formed on or in a flexible interconnect using low cost electronic printing capability. Such features, including sub-micron and multi-layer lines, may be printed on the flexible interconnect using wafer fabrication techniques known to those skilled in such art. FIG. 2 shows a basic flexible interconnect in a flexed state.

The flexible interconnect can be attached to the assembly using materials such as conductive and non-conductive epoxies. The conductive epoxies or similarly suitable material can be applied so as to directly connect the interconnect pad to the pad of the die being contacted with the two surfaces coming into contact when the flexible interconnect is applied.

A more sophisticated interconnection includes the patterning of a via (through-hole) completely through the pads of the flexible interconnect. In addition to the features of the basic flexible interconnect, a top view of an enhanced version of a flexible interconnect is illustrated in FIG. 3 where vias 130 have been formed. Vias extend through the thickness of the flexible material as well as the metal surface of the pad. A side view of the same interconnect appears in FIG. 4, while FIG. 5 depicts a flexed version of the same device. It is to be noted from these figures that the interconnects (110 and 120) are entirely contained within the flexible interconnect material (polymer, 190) so as to provide electrical isolation.

The flexible interconnect can be applied with the flexible interconnect pad surface on the side that is not adjacent to the die pad being contacted. To accomplish this, the flexible interconnect is adhered to the substrate with non-conductive epoxy or with an adhesive. An example of using the flexible interconnect with vias (FIG. 5) in this manner is shown in FIG. 6. Such interconnections may be made between one semiconductor die and another, from a semiconductor die to a printed circuit board (PCB), or between one PCB and another. Here, connection is made between a flexible PCB 140 at pad 145 and a semiconductor die 150 at its pad 160 using a conductive epoxy 170.

The connection is made by printing a fill of conductive material, such as conductive epoxy, into the vias 130. The conductive material serves as a short circuit to the die pad, fills each via and overlaps the top of the flexible interconnect pad to form an electrical path from the die pad to the flexible interconnect pad. The filled vias 130 complete the electrical connection with pads 110 at the opposite side of the flexible interconnect 100. The epoxy fill of the vias maintains the thinness and flexibility of the interconnect. Depending upon the application, the materials being connected, and the relative dimensions, it may be desirable to fill the space between the flexible interconnect and the connected devices with a non-conductive epoxy 180 fill material to provide additional support.

A more complex, two-dimensional, flexible interconnect is shown in FIG. 7. This flexible interconnect 100 is used in FIG. 8 to make connections between two semiconductor die 150 and a substrate 200 such as a flexible PCB. Contact between the bonding pads 160 of the semiconductor die 150 are made by filling the vias with a printed conductive epoxy 170 that overflows onto the surface of the interconnect pad. Depending upon the dimensions, a printable conductive ink may be used in place of the epoxy. The flexible interconnect 100 conforms to the topography of the underlying devices. Though the pads 110 of the flexible interconnect 100 have been shown as being recessed from the surrounding surface, they may be fabricated so as to reach the surface. Depending upon the relative topographies of the mating surfaces, a surface-to-surface connection may be made without epoxy by using pad materials that naturally attach to each other when placed in contact. In any case, the flexible material of the pad is open to accept electrical bonding to a die pad or substrate pad. The flexible interconnect may also be applied to a die by extending, or wrapping, over the edge of the die to a substrate where it is attached using a non-conductive adhesive.

The surface area of the flexible interconnect may be large or relatively larger than the die being connected. The flexible material is large enough, and durable enough, that it can be handled during assembly without undue concern for its fragility. This accommodates ease of positioning that is independent of the die and substrate materials.

At the same time, the interconnect metal may be extremely small. A flexible direct-write printing technology is one means of producing a tightly packed interconnect. Printing with a conductive ink may be used to establish contact between two stacked material layers.

Another means of producing a tightly packed interconnect is to use a Semiconductor-on-Polymer (SOP) technology. Such technology is capable of integrating extremely small, dense devices into the flexible interconnect. Furthermore, the SOP approach allows for integration of in-line devices such as resistors and capacitors, and even active devices. By replacing the conductive metal lines with a transparent material such as silicon, the described flexible interconnect may be adapted for use with optical components through photonic waveguides, providing for a mix of electronic and non-electronic capability.

Metal interconnects may be used to conduct heat or to form heat sinks. Similarly, flexible interconnects may be formed from material that is an electrical insulator but thermally conductive in order to transport heat away from the attached circuitry. By replacing the polymer with an insulator material that conducts heat, the flexible interconnect becomes usable as a conformal heat sink. This is in addition to the fact that unused surface area on the flexible interconnect may be layered with metal lines for the purpose of conducting heat away from the interconnected devices.

Though the above process has been described using flexible semiconductor devices and flexible substrates, there is nothing described here that precludes application of these flexible interconnect techniques to rigid components and there are other advantages to be gained in so doing. In its simplest form the flexible interconnect described here can be used as a replacement for bonding wires, especially as they can span long distances while conforming to underlying topography.

As such, multiple interconnects may be applied simultaneously, each with its own inherent insulation to protect it from the other interconnects, even when deformed. This reduces assembly time and cost while improving reliability. Additionally, the interconnects may comprise multi-layer metal. In some applications it will be useful that individual bonding connections may extend beyond the edge of a die or package.

On the other hand, the described flexible interconnects could be written one at a time using a material such as a conductive epoxy to trace from one pad to another on top of a flexible polymer strip that had been constructed with an array of vias, selectively addressing those contacts necessary to configure a particular circuit. It will be recognized by those skilled in these arts that many combinations and variations of the above-described devices and techniques are possible.

What is claimed is:

1. A flexible interconnect comprising:
a flexible non-conductive material; and
a pattern of flexible conductive material on the flexible non-conductive material,
wherein the pattern includes at least two connection pads coupled by a line, and
wherein the flexible interconnect is flexible, and
wherein a total thickness of the flexible interconnect does not exceed 50 μm.

2. The flexible interconnect of claim 1, wherein the pattern is formed using a Semiconductor-on-Polymer (SOP) process.

3. The flexible interconnect of claim 1, wherein the pattern is formed using ink.

4. The flexible interconnect of claim 1, wherein the flexible non-conductive material is paper.

5. The flexible interconnect of claim 1, wherein the pattern comprises a multiplicity of lines each line of which is insulatable from adjacent lines.

6. The flexible interconnect of claim 1, further comprising a via (through-hole) in a connection pad.

7. The flexible interconnect of claim 1, wherein of the flexible conductive material and the flexible non-conductive material at least one material is thermally conductive, whereby the flexible interconnect serves as a heat sink.

8. The flexible interconnect of claim 1,
wherein two or more of the flexible interconnect are placed one upon another to form a multi-layer flexible interconnect,
wherein the flexible non-conductive material of a first layer serves to insulate the pattern of flexible conductive material of the first layer from the pattern of flexible conductive material of a layer adjacent to the first layer.

9. The flexible interconnect of claim 8, wherein a conductive ink establishes electrical contact from the pattern in the first layer to the pattern in the layer adjacent to the first layer.

10. The flexible interconnect of claim 1,
wherein the pattern of flexible conductive material comprises SOI (Semiconductor-On-Insulator).

11. The flexible interconnect of claim 1, wherein the flexible interconnect has a length greater than 1 cm.

12. An assembly comprising:
a substrate;
a semiconductor die attached to the substrate; and
the flexible interconnect of claim 1,
wherein the flexible interconnect is coupled to the semiconductor die.

13. The assembly of claim 12, wherein the flexible interconnect is adhered to the substrate by a non-conductive epoxy.

14. The assembly of claim 12, wherein the flexible interconnect is adhered to the substrate by a conductive epoxy.

15. The assembly of claim 12, wherein the flexible interconnect is adhered to the substrate by an adhesive.

16. The assembly of claim 12, wherein the flexible interconnect conforms to topography of the assembly.

17. The assembly of claim 12, wherein the flexible interconnect further comprises a via (through-hole) in a connection pad, and
wherein the flexible interconnect is coupled to the semiconductor die by printing a fill of a conductive material into the via.

18. The assembly of claim 17, wherein the pattern of flexible conductive material is on a surface of the flexible interconnect that is not adjacent to the semiconductor die.

19. The assembly of claim 12, wherein the flexible interconnect extends beyond an edge of the semiconductor die.

20. The assembly of claim 12, wherein a conductive material is applied to a connection pad of the flexible interconnect, and
wherein the flexible interconnect couples to the semiconductor die when the flexible interconnect contacts the semiconductor die.
